(19) United States
(12) Patent Application Publication
(10) Pub. No.: US 2023/0089152 A1
(43) Pub. Date: Mar. 23, 2023

(54) CONDUCTIVE FOAM

(71) Applicant: HUIZHOU TCL MOBILE COMMUNICATION CO., LTD, Huizhou, Guangdong (CN)

(72) Inventors: Wei Chen, Huizhou, Guangdong (CN); Song Bai, Huizhou, Guangdong (CN); Weidong Luo, Huizhou, Guangdong (CN)

(73) Assignee: HUIZHOU TCL MOBILE COMMUNICATION CO., LTD, Huizhou, Guangdong (CN)

(21) Appl. No.: 17/758,009

(22) PCT Filed: Feb. 21, 2020
(86) PCT No.: PCT/CN2020/076165

§ 371 Date: Jun. 26, 2022

(30) Foreign Application Priority Data
Dec. 27, 2019 (CN) 201911377001.7

(51) Int. Cl. H05K 9/00

(52) U.S. Cl. CPC H05K 9/0088; H05K 9/009

(57) ABSTRACT

A conductive foam includes a foam body, a conductive cloth, and a conductive adhesive layer. The conductive cloth wraps an outer surface of the foam body and includes a device contact surface configured to contact an external device for assembly. The conductive adhesive layer is disposed on the device contact surface.

### CROSS REFERENCE

The present application claims priority to Chinese Patent Application No. 201911377001.7, titled “conductive foam”, filed on Dec. 27, 2019, with the China National Intellectual Property Administration, which is incorporated by reference in the present application in its entirety.

### FIELD OF INVENTION

The present disclosure relates to the technical field of conductive foams, and particularly to a conductive foam.

### BACKGROUND

With the continuous development of society, conductive foams have been widely used in various industries. A conductive foam is a flame-retardant foam whose outer surface is wrapped with a conductive cloth, has a good surface conductivity, and can be easily fixed on a device to be shielded with an adhesive tape. Some devices inside a mobile terminal are provided with conductive foams, which can conduct electricity, prevent static electricity, and reduce electromagnetic radiation. The conductive foam is a flame-retardant foam whose outer surface is wrapped with a conductive cloth, has a good surface conductivity, and can be easily fixed on a device to be shielded with an adhesive tape. Therefore, the conductive foam is widely used in electronic cages, chassis, indoor cages, industrial equipment, notebook computers, and mobile communication equipment. Sometimes, some devices inside a mobile terminal are provided with conductive foams, which can conduct electricity, prevent static electricity, and reduce electromagnetic radiation.

However, for a conductive foam designed in the prior art, in a process of assembling the conductive foam to a device of a mobile terminal, the conductive foam is often misaligned and dropped, so that it takes a long time to assemble.

### SUMMARY OF DISCLOSURE

The present disclosure provides a conductive foam, which effectively solves a problem that a conductive foam is prone to misalignment and falling when assembling the conductive foam to a device of a mobile terminal.

In a first aspect, the present disclosure provides a conductive foam comprising a foam body, a conductive cloth, and a conductive adhesive layer. The conductive cloth wraps an outer surface of the foam body and comprises a device contact surface configured to contact an external device for assembly. The conductive adhesive layer is disposed on the device contact surface.

In an embodiment, the conductive adhesive layer is centrally disposed on the device contact surface, and an area of the conductive adhesive layer is less than an area of the device contact surface.

In an embodiment, a ratio of the area of the conductive adhesive layer and the area of the device contact surface is any value between ⅓ and ½.

In an embodiment, the conductive cloth is nickel-plated fiber cloth, gold-plated fiber cloth, carbon-plated fiber cloth, or aluminum-plated fiber cloth.

In an embodiment, the conductive adhesive layer is doped with a plurality of metal conductive particles, and the metal conductive particles comprise one or more of gold, silver, copper, aluminum, zinc, iron, and nickel.

In an embodiment, a concentration of the metal conductive particles is inversely proportional to the area of the conductive adhesive layer.

In an embodiment, the conductive adhesive layer comprises a plurality of conductive adhesive sheets arranged at intervals, and at least two of the conductive adhesive sheets are doped with different metal conductive particles.

In an embodiment, the conductive foam further comprises a plurality of through holes. The through holes are arranged in an array and serve as heat dissipation channels for the device in contact with the conductive foam.

In an embodiment, the conductive adhesive layer comprises a dust ring. The dust ring is disposed on the device contact surface and surrounds a peripheral edge of the device contact surface. The dust ring is configured to prevent dust from entering after the external device is assembled with the conductive foam.

In an embodiment, a shape of a longitudinal section of the conductive foam is a rectangle, a triangle, or a trapezoid.

In a second aspect, the present disclosure further provides a conductive foam comprising a foam body, a conductive cloth, a conductive adhesive layer, and a trunk through hole. The conductive cloth wraps an outer surface of the foam body and comprises a device contact surface configured to contact an external device for assembly. The conductive adhesive layer is disposed on the device contact surface. The trunk through hole penetrates through a longitudinal section of the conductive foam.

In an embodiment, the conductive adhesive layer is centrally disposed on the device contact surface, and an area of the conductive adhesive layer is less than an area of the device contact surface.

In an embodiment, a ratio of the area of the conductive adhesive layer and the area of the device contact surface is any value between ⅓ and ½.

In an embodiment, the conductive cloth is nickel-plated fiber cloth, gold-plated fiber cloth, carbon-plated fiber cloth, or aluminum-plated fiber cloth.

In an embodiment, the conductive adhesive layer is doped with a plurality of metal conductive particles, and the metal conductive particles comprise one or more of gold, silver, copper, aluminum, zinc, iron, and nickel.

In an embodiment, a concentration of the metal conductive particles is inversely proportional to the area of the conductive adhesive layer.

In an embodiment, the conductive adhesive layer comprises a plurality of conductive adhesive sheets arranged at intervals, and at least two of the conductive adhesive sheets are doped with different metal conductive particles.

In an embodiment, the conductive foam further comprises a plurality of through holes. The through holes are arranged in an array and serve as heat dissipation channels for the device in contact with the conductive foam.

In an embodiment, the conductive adhesive layer comprises a dust ring. The dust ring is disposed on the device contact surface and surrounds a peripheral edge of the device contact surface. The dust ring is configured to prevent dust from entering after the external device is assembled with the conductive foam.

In an embodiment, a shape of the longitudinal section of the conductive foam is a rectangle, a triangle, or a trapezoid.

Compared with the prior art, the conductive foam provided by the present disclosure comprises a foam body, a conductive cloth, and a conductive adhesive layer, the conductive cloth wraps an outer surface of the foam body and comprises a device contact surface configured to contact an external device for assembly, and the conductive adhesive layer is disposed on the device contact surface. The conductive foam provided by the present disclosure differs from the prior art in that the conductive adhesive layer is disposed on the device contact surface of the conductive cloth, so that when the device contact surface of the conductive foam contacts the external device for assembly, the conductive foam will not be displaced and dropped, thereby shortening assembly time and improving assembly efficiency of the conductive foam.

### BRIEF DESCRIPTION OF DRAWINGS

FIG. 1 is a three-dimensional structure schematic diagram of a conductive foam according to an embodiment of the present disclosure.

FIG. 2 is a three-dimensional structure schematic diagram of another conductive foam according to an embodiment of the present disclosure.

FIG. 3 is a three-dimensional structure schematic diagram of another conductive foam according to an embodiment of the present disclosure.

FIG. 4 is a three-dimensional structure schematic diagram of another conductive foam according to an embodiment of the present disclosure.

### DETAILED DESCRIPTION

The following description of various embodiments of the present disclosure with reference to the accompanying drawings is used to illustrate specific embodiments that can be practiced. And, the described embodiments are merely some of the embodiments of the present disclosure and not all embodiments. All other embodiments obtained by those skilled in the art based on the embodiments of the present disclosure without creative labor are within claimed scope of the present disclosure.

It should be noted that directional terms mentioned in the present disclosure, such as “above”, “below”, “front”, “back”, “left”, “right”, “inside”, “outside”, “side”, are merely used to indicate the direction of the accompanying drawings. Therefore, the directional terms are used for illustrating and understanding the present disclosure rather than limiting the present disclosure. In the figures, elements with similar structure are indicated by the same reference numerals. Thicknesses and shapes in the accompanying drawings of the present disclosure do not reflect real scale, and are only intended to illustrate the embodiments of the present disclosure

A conductive foam is formed by combining a metal fiber cloth and a foam, and after a series of treatments, it has a good surface conductivity and compressibility, so that it is suitable for electromagnetic shielding in a space that is small and has a limited closing pressure.

However, for a conductive foam designed in the prior art, in a process of assembling the conductive foam to a device of a mobile terminal, the conductive foam is often misaligned and dropped, so that it takes a long time to assemble. The present disclosure provides a conductive foam, which effectively solves the problem that a conductive foam is prone to misalignment and falling when assembling the conductive foam to a device of a mobile terminal.

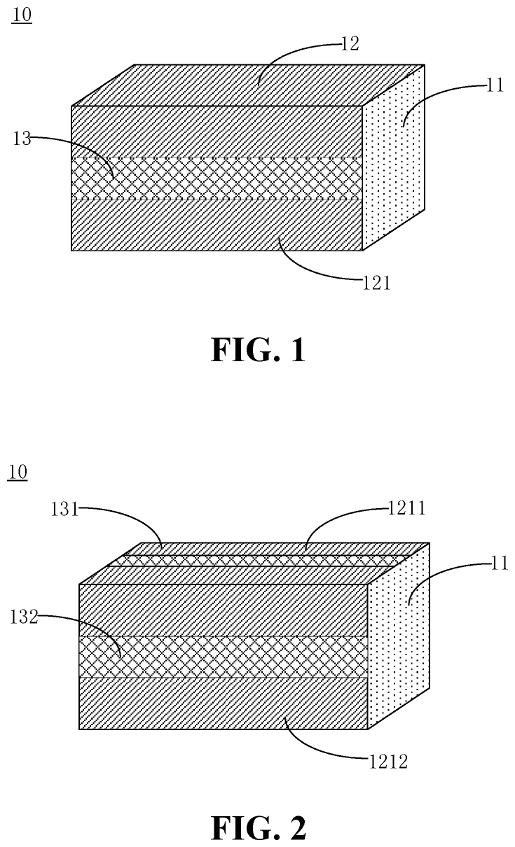

Please refer to FIG. 1, which is a three-dimensional structure schematic diagram of a conductive foam according to an embodiment of the present disclosure, and shows components of the present invention and a positional relationship thereof.

As shown in FIG. 1, a conductive foam 10 comprises a foam body 11, a conductive cloth 12, and a conductive adhesive layer 13. The conductive cloth 12 wraps an outer surface of the foam body 11 and comprises a device contact surface 121. The device contact surface 121 is configured to contact an external device for assembly. The conductive adhesive layer 13 is disposed on the device contact surface 121.

Furthermore, a conductive adhesive is formed by doping a certain proportion of metal conductive particles into an ordinary adhesive, so as to form the conductive adhesive that can conduct electricity. In this production process, because a concentration of the metal conductive particles in the conductive adhesive is not high, gaps between the metal conductive particles are also large. Therefore, when the conductive adhesive is in contact with a metal device, the conductive adhesive has a low on-resistance and has a very poor conductivity, which affects an overall performance of a mobile terminal. Accordingly, if the conductive adhesive layer 13 completely covers the device contact surface 121, because the conductive adhesive layer 13 has a low on-resistance when the conductive adhesive layer 13 is in contact with the metal device, the overall performance of the mobile terminal will be degraded. Therefore, in the conductive foam 10 provided by this embodiment of the present disclosure, an area of the conductive adhesive layer 13 is less than an area of the device contact surface 121, and the conductive adhesive layer 13 is centrally disposed on the device contact surface 121. Optimally, a ratio of the area of the conductive adhesive layer 13 and the area of the device contact surface 121 is any value between ⅓ and ½.

Furthermore, in the conductive foam 10 provided by this embodiment of the present disclosure, the conductive cloth 12 is nickel-plated fiber cloth, gold-plated fiber cloth, carbon-plated fiber cloth, or aluminum-plated fiber cloth. Specifically, because a function of the conductive adhesive layer 13 is mainly used to bond the external device, so as to fix the conductive foam 10 to the external device. The conductive foam 10 mainly relies on the conductive cloth 12 to conduct electricity. The conductive cloth is made of a fiber cloth (generally commonly used polyester fiber cloth) as a base material. After pretreatment, metal is electroplated on the fiber cloth, so that the fiber cloth has metallic properties and becomes the conductive fiber cloth. For example, in the aforementioned nickel-plated fiber cloth, nickel is electroplated on a polyester fiber cloth to make the polyester fiber cloth conductive.

Furthermore, in the conductive foam 10 provided by this embodiment of the present disclosure, the conductive adhesive layer 13 is doped with a plurality of metal conductive particles (not shown), and the metal conductive particles comprise one or more of gold, silver, copper, aluminum, zinc, iron, and nickel.

Furthermore, the conductive adhesive layer 13 may be disposed on the conductive cloth 12 by coating, or the conductive adhesive layer 13 may be made into a double-sided tape and adhered to the conductive cloth 12.

Specifically, because shapes of external devices are different, sometimes one external device have multiple surfaces that need to be in contact with the conductive foam 10, or one conductive foam 10 needs to be in contact with a plurality of external devices. Therefore, in order to meet assembly requirements of different shapes and different numbers of external devices, the conductive foam 10 comprises a plurality of device contact surfaces. In addition, metal conductive particles doped in conductive adhesive layers 13 disposed on the device contact surfaces 121 may also be different.

In a specific embodiment, please refer to FIG. 2, the conductive foam 10 comprises a first device contact surface 1211 and a second device contact surface 1212. The first device contact surface 1211 and the second device contact surface 1212 respectively contact a first metal surface (not shown) and a second metal surface (not shown) of one same external device. An area of the first metal surface is smaller, and an area of the second metal surface is larger. Because the area of the first metal surface is smaller, a first conductive adhesive layer 131 disposed on the first device contact surface 1211 may be doped with silver (Ag) having a better conductivity and higher price. Because the area of the second metal surface is larger, a second conductive adhesive layer 132 disposed on the second device contact surface may be doped with iron (Fe) having a lower conductivity and lower price. In this way, an electrical conductivity of the conductive foam 10 is ensured while reducing a production cost.

In another specific embodiment, the conductive foam 10 comprises a third device contact surface (not shown) and a fourth device contact surface (not shown). The third device contact surface and the fourth device contact surface respectively contact a metal surface of a first external device (not shown) and a metal surface of a second external device (not shown). An area of the metal surface of the first external device is smaller, and an area of the metal surface of the second external device is larger. Because the area of the metal surface of the first external device is smaller, a third conductive adhesive layer (not shown) disposed on the third device contact surface may be doped with silver (Ag) having the better conductivity and higher price. Because the area of the metal surface of the second external device is larger, a fourth conductive adhesive layer (not shown) disposed on the fourth device contact surface may be doped with iron (Fe) having the lower conductivity and lower price. In this way, the electrical conductivity of the conductive foam 10 is ensured while reducing the production cost.

Furthermore, the conductive foam 10 provided by this embodiment of the present disclosure may be in a compressed state after being assembled. In some cases, when the conductive foam 10 is in contact with the external device, a space reserved for the conductive foam 10 is very small. Therefore, in order to save an assembly space for the conductive foam and save the production cost, the conductive foam 10 may further comprise a trunk through hole (not shown) penetrating through its longitudinal section. A shape of a longitudinal section of the trunk through hole is a rectangle, a triangle, a circle, an arch, or a trapezoid.

Furthermore, in the conductive foam 10 provided by this embodiment of the present disclosure, in order to ensure a conductivity and viscosity of the conductive adhesive, a concentration of the metal conductive particles is inversely proportional to an area of the conductive adhesive layer 13.

Furthermore, a shape of the longitudinal section of the conductive foam 10 provided by this embodiment of the present disclosure is a rectangle, a triangle, or a trapezoid.

Furthermore, the conductive foam 10 provided by this embodiment of the present disclosure further comprises a plurality of through holes (not shown) arranged in an array to serve as heat dissipation channels for the device in contact with the conductive foam 10. The number of the through holes is proportional to the area of the device contact surface 121. That is, the larger the area of the device contact surface 121, the larger the number of the through holes. The smaller the area of the device contact surface 121, the smaller the number of the through holes.

Differs from the prior art, a conductive foam 10 provided by the present disclosure comprises a foam body 11, a conductive cloth 12, and a conductive adhesive layer 13, the conductive cloth 12 wraps an outer surface of the foam body 11 and comprises a device contact surface 121 configured to contact an external device for assembly, and the conductive adhesive layer 13 is disposed on the device contact surface 121. In the conductive foam 10, the conductive adhesive layer 13 is disposed on the device contact surface 121 of the conductive cloth 12, so that when the device contact surface 121 of the conductive foam 10 contacts the external device for assembly, the conductive foam 10 will not be displaced and dropped, thereby shortening assembly time and improving assembly efficiency of the conductive foam 10.

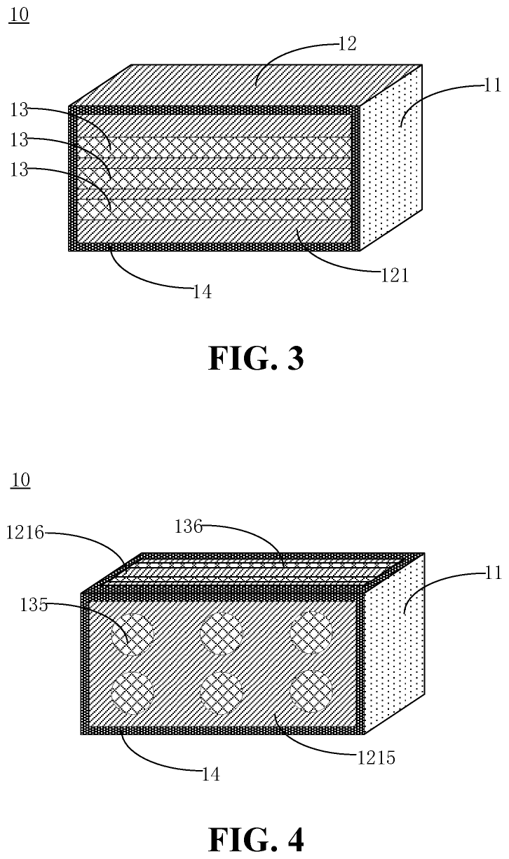

Please refer to FIG. 3, which is a three-dimensional structure schematic diagram of another conductive foam according to an embodiment of the present disclosure, and shows components of the present invention and a positional relationship thereof.

As shown in FIG. 3, a conductive foam 10 comprises a foam body 11, a conductive cloth 12, a conductive adhesive layer 13, and a dust ring 14. The conductive cloth 12 wraps an outer surface of the foam body 11 and comprises a device contact surface 121. The device contact surface 121 is configured to contact an external device for assembly. The conductive adhesive layer 13 is disposed on the device contact surface 121. The conductive adhesive layer 13 comprises a plurality of conductive adhesive sheets (not shown) arranged at intervals. The dust ring 14 is configured to prevent dust from entering after the external device is assembled with the conductive foam 10. The dust ring 14 is disposed on the device contact surface 121 and surrounds a peripheral edge of the device contact surface 121.

Furthermore, a conductive adhesive is formed by doping a certain proportion of metal conductive particles into an ordinary adhesive, so as to form the conductive adhesive that can conduct electricity. In this production process, because a concentration of the metal conductive particles in the conductive adhesive is not high, gaps between the metal conductive particles are also large. Therefore, when the conductive adhesive is in contact with a metal device, the conductive adhesive has a low on-resistance and has a very poor conductivity, which affects an overall performance of a mobile terminal. Accordingly, if the conductive adhesive layer 13 completely covers the device contact surface 121, because the conductive adhesive layer 13 has a low on-resistance when the conductive adhesive layer 13 is in contact with the metal device, the overall performance of the mobile terminal will be degraded. Therefore, in the conductive foam 10 provided by this embodiment of the present disclosure, an area of the conductive adhesive layer 13 is less than an area of the device contact surface 121, and the conductive adhesive layer 13 is centrally disposed on the device contact surface 121. Optimally, a ratio of the area of the conductive adhesive layer 13 and the area of the device contact surface 121 is any value between ⅓ and ½.

Furthermore, in the conductive foam 10 provided by this embodiment of the present disclosure, the conductive cloth 12 is nickel-plated fiber cloth, gold-plated fiber cloth, carbon-plated fiber cloth, or aluminum-plated fiber cloth. Specifically, because a function of the conductive adhesive layer 13 is mainly used to bond the external device, so as to fix the conductive foam 10 to the external device. The conductive foam 10 mainly relies on the conductive cloth 12 to conduct electricity. The conductive cloth is made of a fiber cloth (generally commonly used polyester fiber cloth) as a base material. After pretreatment, metal is electroplated on the fiber cloth, so that the fiber cloth has metallic properties and becomes the conductive fiber cloth. For example, in the aforementioned nickel-plated fiber cloth, nickel is electroplated on a polyester fiber cloth to make the polyester fiber cloth conductive.

Furthermore, in the conductive foam 10 provided by this embodiment of the present disclosure, the conductive adhesive layer 13 is doped with a plurality of metal conductive particles (not shown), and the metal conductive particles comprise one or more of gold, silver, copper, aluminum, zinc, iron, and nickel.

Furthermore, the conductive adhesive layer 13 may be disposed on the conductive cloth 12 by coating, or the conductive adhesive layer 13 may be made into a double-sided tape and adhered to the conductive cloth 12.

Specifically, because shapes of external devices are different, sometimes one external device have multiple surfaces that need to be in contact with the conductive foam 10, or one conductive foam 10 needs to be in contact with a plurality of external devices. Therefore, in order to meet assembly requirements of different shapes and different numbers of external devices, the conductive foam 10 comprises a plurality of device contact surfaces. In addition, metal conductive particles doped in conductive adhesive layers 13 disposed on the device contact surfaces 121 may also be different.

In a specific embodiment, please refer to FIG. 2, the conductive foam 10 comprises a first device contact surface (not shown) and a second device contact surface (not shown). The first device contact surface and the second device contact surface respectively contact a first metal surface and a second metal surface of one same external device (not shown). An area of the first metal surface is smaller, and an area of the second metal surface is larger. Because the area of the first metal surface is smaller, a first conductive adhesive layer (not shown) disposed on the first device contact surface 1211 may be doped metal conductive particles (such as silver or copper) having a better conductivity and higher price. Because the area of the second metal surface is larger, a second conductive adhesive layer (not shown) disposed on the second device contact surface may be doped with metal conductive particles (such as aluminum or iron) having a lower conductivity and lower price. In this way, an electrical conductivity of the conductive foam 10 is ensured while reducing a production cost.

In another specific embodiment, the conductive foam 10 comprises a third device contact surface (not shown) and a fourth device contact surface (not shown). The third device contact surface and the fourth device contact surface respectively contact a metal surface of a first external device (not shown) and a metal surface of a second external device (not shown). An area of the metal surface of the first external device is smaller, and an area of the metal surface of the second external device is larger. Because the area of the metal surface of the first external device is smaller, a third conductive adhesive layer (not shown) disposed on the third device contact surface may be doped with the metal conductive particles (such as silver or copper) having the better conductivity and higher price. Because the area of the metal surface of the second external device is larger, a fourth conductive adhesive layer (not shown) disposed on the fourth device contact surface may be doped with the metal conductive particles (such as aluminum or iron) having the lower conductivity and lower price. In this way, the electrical conductivity of the conductive foam 10 is ensured while reducing the production cost.

Furthermore, the conductive adhesive layer 13 comprises a plurality of conductive adhesive sheets (not shown) arranged at intervals, and at least two of the conductive adhesive sheets are doped with different metal conductive particles. For example, one of the conductive adhesive sheets is doped with the metal conductive particles (such as silver or copper) having the better conductivity and higher price, and the other conductive adhesive sheets are doped with the metal conductive particles (such as aluminum or iron) having the lower conductivity and lower price. In this way, the electrical conductivity of the conductive foam 10 is ensured while reducing the production cost.

Furthermore, the conductive adhesive sheets may be shaped as rectangles or circles. When the conductive adhesive sheets may be shaped as rectangles, the conductive adhesive sheets may be arranged on the device contact surface 121 at intervals. When the conductive adhesive sheets may be shaped as circles, the conductive adhesive sheets may be arranged on the device contact surface 121 in an array.

In another specific embodiment, please refer to FIG. 4, the conductive foam 10 comprises a fifth device contact surface 1211 and a sixth device contact surface 1212. A fifth conductive adhesive layer 131 disposed on the fifth contact surface 1211 is composed of six circular conductive adhesive sheets. A sixth conductive adhesive layer 132 disposed on the sixth contact surface 1212 is composed of two rectangular conductive adhesive sheets. In the fifth conductive adhesive layer 131, one of the conductive adhesive sheets is doped with silver (Ag) having the better conductivity and higher price, and the other conductive adhesive sheets are doped with iron (Fe) having the lower conductivity and lower price. In the sixth conductive adhesive layer 132, one of the conductive adhesive sheets is doped with silver (Ag) having the better conductivity and higher price, and the other conductive adhesive sheet is doped with iron (Fe) having the lower conductivity and lower price. In this way, the electrical conductivity of the conductive foam 10 is ensured while reducing the production cost.

Furthermore, the conductive foam 10 provided by this embodiment of the present disclosure may be in a compressed state after being assembled. In some cases, when the conductive foam 10 is in contact with the external device, a space reserved for the conductive foam 10 is very small. Therefore, in order to save an assembly space for the conductive foam and save the production cost, the conductive foam 10 may further comprise a trunk through hole (not shown) penetrating through its longitudinal section. A shape of a longitudinal section of the trunk through hole is a rectangle, a triangle, a circle, an arch, or a trapezoid.

Furthermore, in the conductive foam 10 provided by this embodiment of the present disclosure, in order to ensure a conductivity and viscosity of the conductive adhesive, a concentration of the metal conductive particles is inversely proportional to an area of the conductive adhesive layer 13.

Furthermore, a shape of the longitudinal section of the conductive foam 10 provided by this embodiment of the present disclosure is a rectangle, a triangle, or a trapezoid.

Furthermore, the conductive foam 10 provided by this embodiment of the present disclosure further comprises a plurality of through holes (not shown) arranged in an array to serve as heat dissipation channels for the device in contact with the conductive foam 10. The number of the through holes is proportional to the area of the device contact surface 121. That is, the larger the area of the device contact surface 121, the larger the number of the through holes. The smaller the area of the device contact surface 121, the smaller the number of the through holes.

Differs from the prior art, a conductive foam 10 provided by the present disclosure comprises a foam body 11, a conductive cloth 12, and a conductive adhesive layer 13, the conductive cloth 12 wraps an outer surface of the foam body 11 and comprises a device contact surface 121 configured to contact an external device for assembly, and the conductive adhesive layer 13 is disposed on the device contact surface 121. In the conductive foam 10, the conductive adhesive layer 13 is disposed on the device contact surface 121 of the conductive cloth 12, so that when the device contact surface 121 of the conductive foam 10 contacts the external device for assembly, the conductive foam 10 will not be displaced and dropped, thereby shortening assembly time and improving assembly efficiency of the conductive foam 10. Moreover, because the conductive foam 10 further comprises a dust ring 14 disposed on the device contact surface 121, and the dust ring 14 surrounds a peripheral edge of the device contact surface 121, so as to prevent dust from entering the device in contact with the conductive foam 10.

In addition to the aforementioned embodiments, the present disclosure may also have other implementations. All technical solutions formed by equal replacement or equivalent replacement fall within the claimed scope of the present disclosure.

In the above, the present application has been described in the above preferred embodiments, but the preferred embodiments are not intended to limit the scope of the present application, and those skilled in the art may make various modifications without departing from the scope of the present application. The scope of the present application is determined by claims.

What is claimed is:

1. A conductive foam, comprising:
a foam body;
a conductive cloth wrapping an outer surface of the foam body and comprising a device contact surface configured to contact an external device for assembly; and
a conductive adhesive layer disposed on the device contact surface.

2. The conductive foam according to claim 1, wherein the conductive adhesive layer is centrally disposed on the device contact surface, and an area of the conductive adhesive layer is less than an area of the device contact surface.

3. The conductive foam according to claim 2, wherein a ratio of the area of the conductive adhesive layer and the area of the device contact surface is any value between ⅓ and ½.

4. The conductive foam according to claim 1, wherein the conductive cloth is nickel-plated fiber cloth, gold-plated fiber cloth, carbon-plated fiber cloth, or aluminum-plated fiber cloth.

5. The conductive foam according to claim 1, wherein the conductive adhesive layer is doped with a plurality of metal conductive particles, and the metal conductive particles comprise one or more of gold, silver, copper, aluminum, zinc, iron, and nickel.

6. The conductive foam according to claim 5, wherein a concentration of the metal conductive particles is inversely proportional to an area of the conductive adhesive layer.

7. The conductive foam according to claim 5, wherein the conductive adhesive layer comprises a plurality of conductive adhesive sheets arranged at intervals, and at least two of the conductive adhesive sheets are doped with different metal conductive particles.

8. The conductive foam according to claim 1, further comprising:
a plurality of through holes arranged in an array to serve as heat dissipation channels for the device in contact with the conductive foam.

9. The conductive foam according to claim 1, further comprising:
a dust ring disposed on the device contact surface, surrounding a peripheral edge of the device contact surface, and configured to prevent dust from entering after the external device is assembled with the conductive foam.

10. The conductive foam according to claim 1, wherein a shape of a longitudinal section of the conductive foam is a rectangle, a triangle, or a trapezoid.

11. A conductive foam, comprising:
a foam body;
a conductive cloth wrapping an outer surface of the foam body and comprising a device contact surface configured to contact an external device for assembly;
a conductive adhesive layer disposed on the device contact surface; and
a trunk through hole penetrating through a longitudinal section of the conductive foam.

12. The conductive foam according to claim 11, wherein the conductive adhesive layer is centrally disposed on the device contact surface, and an area of the conductive adhesive layer is less than an area of the device contact surface.

13. The conductive foam according to claim 12, wherein a ratio of the area of the conductive adhesive layer and the area of the device contact surface is any value between ⅓ and ½.

14. The conductive foam according to claim 11, wherein the conductive cloth is nickel-plated fiber cloth, gold-plated fiber cloth, carbon-plated fiber cloth, or aluminum-plated fiber cloth.

15. The conductive foam according to claim 11, wherein the conductive adhesive layer is doped with a plurality of metal conductive particles, and the metal conductive particles comprise one or more of gold, silver, copper, aluminum, zinc, iron, and nickel.

16. The conductive foam according to claim 15, wherein a concentration of the metal conductive particles is inversely proportional to an area of the conductive adhesive layer.

17. The conductive foam according to claim 15, wherein the conductive adhesive layer comprises a plurality of conductive adhesive sheets arranged at intervals, and at least two of the conductive adhesive sheets are doped with different metal conductive particles.

18. The conductive foam according to claim 11, further comprising:
a plurality of through holes arranged in an array to serve as heat dissipation channels for the device in contact with the conductive foam.

19. The conductive foam according to claim 11, further comprising:
a dust ring disposed on the device contact surface, surrounding a peripheral edge of the device contact surface, and configured to prevent dust from entering after the external device is assembled with the conductive foam.

20. The conductive foam according to claim 11, wherein a shape of the longitudinal section of the conductive foam is a rectangle, a triangle, or a trapezoid.
